(19) United States
(12) Patent Application Publication
(10) Pub. No.: US 2025/0149389 A1
(43) Pub. Date: May 8, 2025

(54) SUBSTRATE PROCESSING METHOD AND SUBSTRATE PROCESSING APPARATUS

(71) Applicant: SEMES CO., LTD., Cheonan-si (KR)

(72) Inventors: Il Young KIM, Cheonan-si (KR); Seong Kwang LEE, Cheonan-si (KR); Hahn Joo YOON, Cheonan-si (KR); Yong Hoon SUNG, Cheonan-si (KR); Sang Man PARK, Cheonan-si (KR); Tae Wan KIM, Cheonan-si (KR); Jun Ho SEO, Cheonan-si (KR)

(73) Assignee: SEMES CO., LTD., Cheonan-si (KR)

(21) Appl. No.: 18/787,320

(22) Filed: Jul. 29, 2024

(30) Foreign Application Priority Data
Nov. 8, 2023 (KR) 10-2023-0153583

(51) Int. Cl. H01L 21/66; H01J 37/32; H01L 21/67

(52) U.S. Cl. CPC H01L 22/26; H01J 37/32449; H01J 37/32522; H01L 21/67115; H01J 2237/3341; H01J 2237/338

(57) ABSTRACT

Disclosed are a substrate processing method and a substrate processing apparatus. The substrate processing method of etching a thin film formed on a substrate in units of atomic layers includes a modifying step of supplying a modifying gas to a processing space in a chamber accommodating the substrate to modify a surface of the thin film and form a modified film having a first thickness, a surface adsorption step of supplying a precursor to the processing space to adsorb the precursor to the modified surface of the thin film, and an etching step of supplying heat to the substrate adsorbed with the precursor to etch the modified surface of the thin film adsorbed with the precursor. The surface adsorption step and the etching step are repeatedly performed multiple times until the modified film having the first thickness is etched.

### BACKGROUND OF THE INVENTION

### Field of the Invention

The present invention relates to a substrate processing method and a substrate processing apparatus, and more particularly, to a substrate processing method capable of shortening a total processing time.

### Description of the Related Art

With the recent demand for miniaturization and high integration of semiconductor devices, a chip area has been increased in proportion to increase in memory capacity. However, the area of a cell region, in which patterns of a semiconductor device are actually formed, has been reduced. Therefore, in order to secure a desired memory capacity, as many patterns as possible need to be formed in a limited cell region. Thus, a critical dimension of a pattern is being gradually reduced. Precise control of an etching process is required in order to form a pattern having a reduced critical dimension.

In general, an etching process may be divided into wet etching and dry etching according to an etching method. Wet etching is isotropic etching using a chemical reaction, and has advantages of low cost and simple process, but has problems of difficulty in achieving accurate etching and occurrence of contamination by chemical substances. In particular, wet etching has a drawback of difficulty in forming fine patterns due to etching errors.

In order to solve the above problems, dry etching may be used. Dry etching is an etching method that uses reactive gas particles in a plasma state. Dry etching is anisotropic etching, and enables accurate etching and thus is widely used to manufacture fine-patterned substrates such as high-density integrated circuits.

Atomic layer etching (ALE), one of the drying etching methods, may include a cycle consisting of surface modification (or adsorption), purging, desorption, and purging, and an object to be etched may be etched through the adsorption and desorption processes. In theory, one atomic layer may be etched in one cycle, and the cycle may be repeated until a desired depth is reached. In addition, atomic layer etching has self-limiting characteristics in which reaction automatically stops when a surface is saturated, and thus has an advantage in that as many layers as desired are accurately removed.

However, atomic layer etching has disadvantages of a very long processing time and resultant low productivity.

### SUMMARY OF THE INVENTION

The present invention has been made to solve the above problems, and it is an object of the present invention to provide a substrate processing method capable of shortening a processing time of atomic layer etching.

The objects to be accomplished by the invention are not limited to the above-mentioned object, and other objects not mentioned herein will be clearly understood by those skilled in the art from the following description.

In accordance with an aspect of the present invention, the above and other objects can be accomplished by the provision of a substrate processing method of etching a thin film formed on a substrate in units of atomic layers, the substrate processing method including a modifying step of supplying a modifying gas to a processing space in a chamber accommodating the substrate to modify a surface of the thin film and form a modified film having a first thickness, a surface adsorption step of supplying a precursor to the processing space to adsorb the precursor to the modified surface of the thin film, and an etching step of supplying heat to the substrate adsorbed with the precursor to etch the modified surface of the thin film adsorbed with the precursor, wherein the surface adsorption step and the etching step are repeatedly performed multiple times until the modified film having the first thickness is etched.

In one embodiment, the substrate processing method may further include a first determination step of determining whether the surface adsorption step and the etching step are repeatedly performed a predetermined number of times.

In one embodiment, upon determining in the first determination step that the surface adsorption step and the etching step have not been repeatedly performed the predetermined number of times, the method may include re-performing the surface adsorption step and the etching step.

In one embodiment, upon determining in the first determination step that the surface adsorption step and the etching step have been repeatedly performed the predetermined number of times, the method may include a second determination step of determining whether a total etching thickness reaches a target etching thickness, and upon determining in the second determination step that the total etching thickness has not reached the target etching thickness, the method may include re-performing the modifying step.

In one embodiment, the modifying step may be controlled such that a modified film forming process is performed in a diffusion limited region.

In one embodiment, in the modifying step, the modifying gas supplied to the substrate may include at least one of oxygen, fluorine, or chlorine.

In one embodiment, the modifying step may be performed in a state of generating plasma in the processing space.

In one embodiment, any one of trimethylamine (TMA), acetylacetone (AcAc), and hexafluoroacetylacetone (hfac) may be supplied to the substrate as the precursor to be adsorbed to a surface of the modified film.

In one embodiment, the modifying step may be controlled at a first temperature, the surface adsorption step may be controlled at a second temperature identical to the first temperature, and the etching step may be controlled at a third temperature higher than the first temperature and the second temperature.

In accordance with another aspect of the present invention, there is provided a substrate processing apparatus including a first chamber configured to modify a thin film formed on a substrate, a second chamber configured to etch the substrate modified in the first chamber in units of atomic layers, a substrate transferring robot configured to transfer the substrate between the first chamber and the second chamber, and a controller, wherein the first chamber includes a plasma generation unit configured to generate plasma in a processing space in the first chamber and a gas supply unit configured to selectively supply a modifying gas and a precursor to the processing space in the first chamber, the second chamber includes a heating unit configured to supply heat to a processing space in the second chamber, and the controller is configured to control the plasma generation unit and the gas supply unit to perform a modifying step of supplying the modifying gas to the processing space in the first chamber to modify a surface of the thin film of the substrate disposed in the processing space in the first chamber and form a modified film having a first thickness, control the gas supply unit to perform a surface adsorption step of supplying the precursor to the processing space in the first chamber to adsorb the precursor to the modified surface of the thin film, control the substrate transferring robot to transfer the substrate having undergone the surface adsorption step to the second chamber, control the heating unit to perform an etching step of supplying heat to the substrate transferred to the second chamber to etch the modified surface of the thin film adsorbed with the precursor, and perform control such that the surface adsorption step and the etching step are repeatedly performed multiple times until the modified film having the first thickness is etched.

In one embodiment, the modifying gas may include at least one of oxygen, fluorine, or chlorine.

In one embodiment, the precursor may be any one of trimethylamine (TMA), acetylacetone (AcAc), and hexafluoroacetylacetone (hfac).

In one embodiment, the controller may control the plasma generation unit and the gas supply unit so that plasma of the modifying gas is generated in the processing space in the first chamber to modify a surface of the thin film formed on the substrate and the precursor is supplied to be adsorbed to the modified surface of the thin film.

In one embodiment, the heating unit may be any one of an infrared lamp, a laser generator, and a microwave generator.

In one embodiment, the controller may perform control such that a modified film forming process of the modifying step is performed in a diffusion limited region.

In one embodiment, the controller may control the gas supply unit not to supply gas to the second chamber while the heating unit of the second chamber is driven.

In accordance with still another aspect of the present invention, there is provided a substrate processing method of etching a thin film formed on a substrate using a substrate processing apparatus including a first chamber and a second chamber, the substrate processing method including a modifying process of modifying the thin film formed on the substrate in the first chamber, the modifying process including a modifying step of supplying a modifying gas to a processing space in the first chamber accommodating the substrate to modify the thin film and to form a modified film having a first thickness, a first purging step of supplying a purge gas to the processing space in the first chamber to remove the modifying gas remaining in the processing space, a surface adsorption step of supplying a precursor to the processing space in the first chamber to adsorb the precursor to a surface of the modified film, and a second purging step of supplying a purge gas to the processing space in the first chamber to remove the precursor remaining in the processing space, an etching process of etching the thin film modified in the first chamber in units of atomic layers in the second chamber, the etching process including an etching step of supplying heat to a processing space in the second chamber to etch the substrate adsorbed with the precursor and a third purging step of supplying a purge gas to the processing space in the second chamber to remove etching by-products remaining in the processing space, and a first determination step of determining whether the surface adsorption step and the etching step are repeatedly performed a predetermined number of times, wherein, upon determining in the first determination step that the surface adsorption step and the etching step have not been repeatedly performed the predetermined number of times, the method includes re-performing the surface adsorption step and the etching step.

In one embodiment, upon determining in the first determination step that the surface adsorption step and the etching step have been repeatedly performed the predetermined number of times, the method may include a second determination step of determining whether a total etching thickness reaches a target etching thickness, and upon determining in the second determination step that the total etching thickness has not reached the target etching thickness, the method may include re-performing the modifying step.

In one embodiment, the modifying step may be controlled such that a modified film forming process is performed in a diffusion limited region.

In one embodiment, the modifying gas may include any one of oxygen, fluorine, and chlorine, and the precursor may be any one of trimethylamine (TMA), acetylacetone (AcAc), and hexafluoroacetylacetone (hfac).

### BRIEF DESCRIPTION OF THE DRAWINGS

The above and other objects, features, and other advantages of the present invention will be more clearly understood from the following detailed description taken in conjunction with the accompanying drawings, in which:

FIG. 1 is a flowchart showing a substrate processing method according to an embodiment of the present invention;

FIG. 2 is a graph of growth of a silicon oxide film;

FIG. 3 is a view of a semiconductor manufacturing facility according to an embodiment of the present invention;

FIG. 4 is a view showing a first chamber according to an embodiment of the present invention; and

FIG. 5 is a view showing a second chamber according to an embodiment of the present invention.

### DETAILED DESCRIPTION OF THE INVENTION

Hereinafter, embodiments of the present invention will be described in detail with reference to the accompanying drawings so that those skilled in the art can easily carry out the embodiments. The present invention may, however, be embodied in many different forms, and should not be construed as being limited to the embodiments set forth herein.

In the following description of the embodiments of the present invention, a detailed description of known functions or configurations incorporated herein will be omitted when it may unnecessarily obscure the subject matter of the present invention. Throughout the drawings, parts performing similar functions and operations are denoted by the same reference numerals.

At least some of the terms used in this specification are terms defined taking into consideration the functions obtained in accordance with the present invention, and may be changed in accordance with the intention of users or operators or usual practice. Therefore, the definitions of these terms should be determined based on the total content of this specification.

As used herein, singular forms may include plural forms, unless the context clearly indicates otherwise. Additionally, the term “comprise”, “include”, or “have” described herein should be interpreted not to exclude other elements but to further include such other elements unless mentioned otherwise.

In the drawings, the sizes or shapes of elements and thicknesses of lines may be exaggerated for clarity and convenience of description.

Hereinafter, embodiments of the present invention will be described in detail with reference to the accompanying drawings, and the same or similar elements are denoted by the same reference numerals even though they are depicted in different drawings, and redundant descriptions thereof will be omitted.

A substrate according to an embodiment of the present invention may be a silicon substrate based on a semiconductor wafer or may be a silicon substrate having a thin film formed thereon. A thin film according to an embodiment of the present invention may be a metal film or an insulating film.

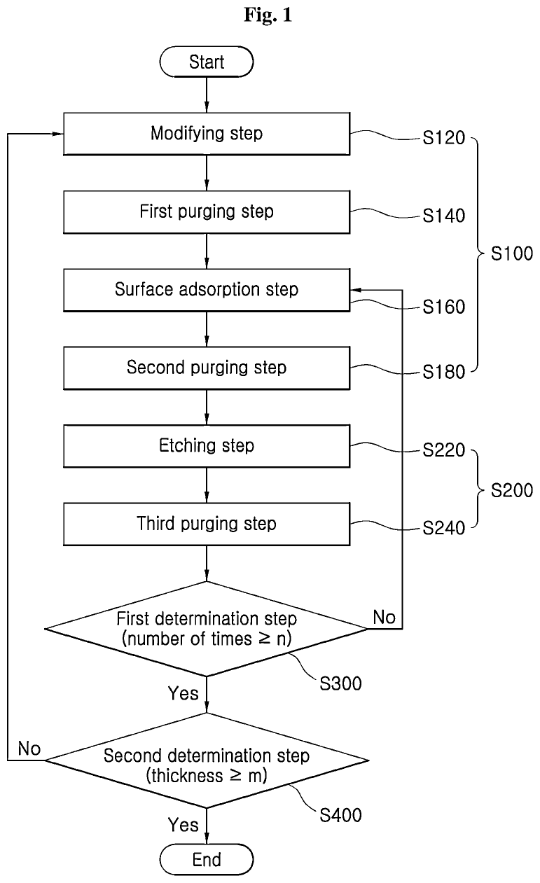

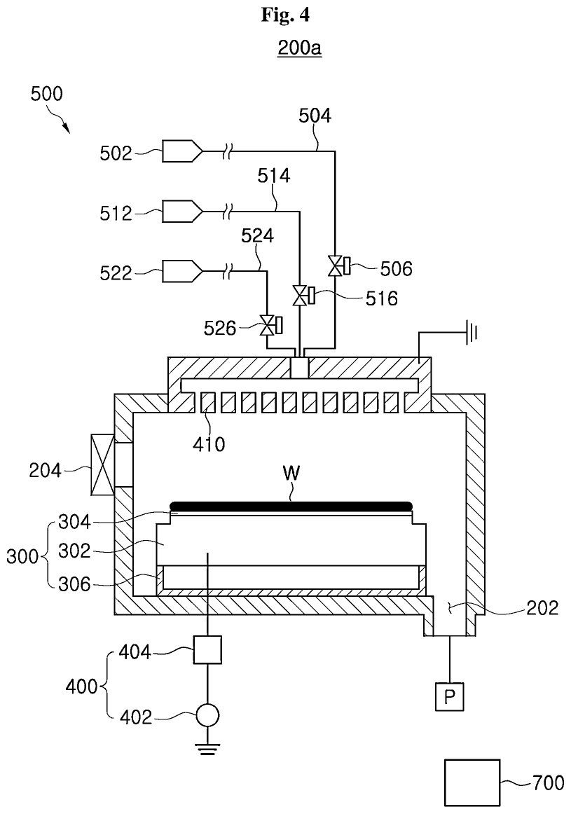

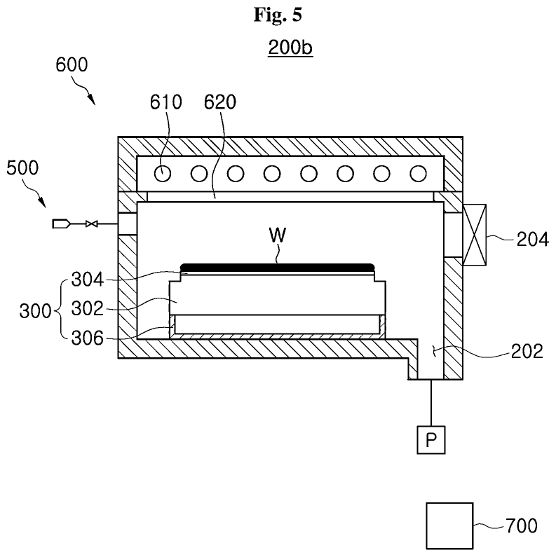

FIG. 1 is a flowchart of a substrate processing method according to an embodiment of the present invention, and FIGS. 4 and 5 are views showing a first chamber and a second chamber configured to perform a substrate processing method of the present invention. The substrate processing method of the present invention will be described with reference to FIGS. 1, 4, and 5.

Referring to FIGS. 1, 4, and 5, a method of etching a thin film formed on a substrate in units of atomic layers according to an embodiment of the present invention may include a modifying step (S120) of supplying a modifying gas to a processing space in a chamber in which the substrate is disposed to modify a surface of the thin film and form a modified film having a first thickness, a first purging step (S140) of supplying a purge gas to the processing space to remove the modifying gas remaining in the processing space, a surface adsorption step (S160) of supplying a precursor to the processing space to adsorb the precursor to the modified surface of the thin film, a second purging step (S180) of supplying a purge gas to the processing space to remove the precursor remaining in the processing space, an etching step (S220) of supplying heat to the substrate adsorbed with the precursor to etch the modified surface of the thin film adsorbed with the precursor, and a third purging step (S240) of supplying a purge gas to the processing space to remove etching by-products. In this case, the modifying step to the second purging step (S120 to S180) may constitute a modifying process (S100), and the etching step (S220) and the third purging step (S240) may constitute an etching process (S200). In addition, according to the embodiment of the present invention, the modifying process (S100) may be performed in a first chamber 200a, and the etching process (S200) may be performed in a second chamber 200b.

In the modifying step (S120), a modifying gas may be supplied to the processing space in the first chamber 200a in which the substrate W is disposed. A gas supply unit 500 may supply the modifying gas, and the supplied modifying gas may be converted into plasma and may then be supplied to the substrate W. The modifying gas converted into plasma may react with the thin film formed on the substrate W to form a modified film having a first thickness. The modifying gas according to the embodiment of the present invention may include any one of oxygen (O), fluorine (F), and chlorine (Cl). The modifying step (S120) may be performed at a first temperature, and the first temperature may be room temperature.

Unlike general atomic layer etching in which the modifying process (S100) is performed once and the etching process (S200) is performed once, the present invention is characterized in that the modifying process (S100) is performed such that the modifying step (S120) is performed once and then the surface adsorption step (S160) and the etching step (S220) are repeatedly performed multiple times. To this end, according to the present invention, a modified film having a predetermined thickness may be formed in the modifying step (S120).

In order to form a modified film having a predetermined thickness in the modifying step (S120), a graph of growth of a modified film over a modifying time may be obtained in advance and may then be utilized. For example, if the modified film is a silicon oxide film, a graph of growth of a silicon oxide film over a process time may be utilized.

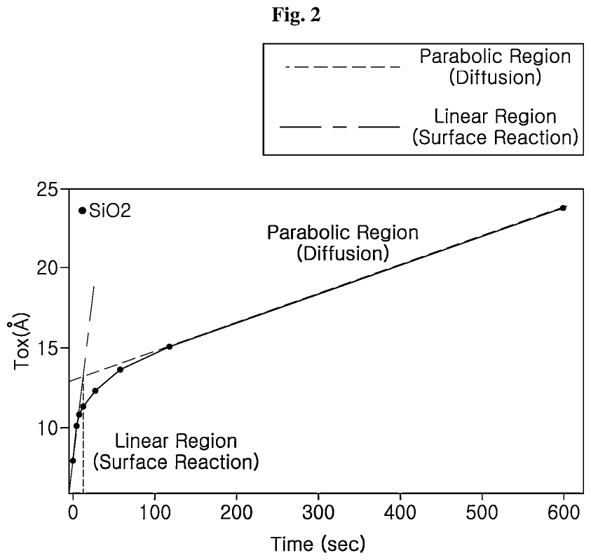

FIG. 2 is a graph of growth of a silicon oxide film.

Referring to FIG. 2, when an oxide film is formed on a silicon substrate, the thickness of the oxide film increases linearly over time at the beginning of the reaction and thereafter increases parabolically over time. This is because the thickness of the oxide film is relatively small at the beginning of the reaction, so the growth rate of the oxide film is determined by the reaction rate at the interface between the oxide film and silicon, but when the thickness of the oxide film increases to a certain extent, the growth rate of the oxide film is determined by the diffusion rate through the oxide film rather than the reaction rate at the interface between the oxide film and silicon. In this case, a region in which the growth rate of the oxide film is determined by the reaction rate will be referred to as a “surface reaction limited region”, and a region in which the growth rate of the oxide film is determined by the diffusion rate will be referred to as a “diffusion limited region”. Therefore, when the modified film is an oxide film, the growth graph shown in FIG. 2 may be obtained through experimentation, and then a modified film having a predetermined thickness may be formed using the modifying time corresponding to the target thickness of the modified film.

In the present invention, a modified film having a sufficient thickness is formed, and it is preferable to form a modified film in the diffusion limited region in which relatively precise thickness control is possible. That is, it is preferable to form a modified film having a predetermined thickness during a modifying process time equal to or longer than the time corresponding to the intersection between the linearly increasing section and the parabolically increasing section in the graph shown in FIG. 2.

The thickness of the modified film may be measured using an ellipsometer. In one embodiment of the present invention, O₂ plasma is supplied to the silicon substrate for about 12 seconds, and the thickness of the formed silicon oxide film (modified film) is measured using an ellipsometer. The measurement result shows that the thickness of the formed silicon oxide film is about 11.4 Å. It may be seen from the above experimental result that the surface layer of the substrate W is modified and a modified film having a predetermined thickness is formed in the modifying step (S120).

The first purging step (S140) is a step of supplying, by the gas supply unit 500, a purge gas to remove the modifying gas remaining in the processing space in the first chamber 200a. After the supply of the modifying gas is interrupted, the purge gas may be directly supplied to the processing space in the first chamber 200a without using plasma. Due to the supply of the purge gas, the modifying gas remaining in the processing space in the first chamber 200a after being supplied in the modifying step (S120) and reaction by-products may be removed from the processing space. An inert gas, such as argon (Ar), helium (He), or nitrogen (N₂), may be used as the purge gas.

The surface adsorption step (S160) is a step of supplying a precursor to the processing space in the first chamber 200a using the gas supply unit 500 to adsorb the precursor to the surface of the thin film modified in the modifying step (S120). The precursor is physically adsorbed to the surface layer of the modified thin film. Thereafter, binding energy may be weakened through a ligand exchange reaction as compared to before performance of the surface adsorption step (S160) without etching the modified film formed on the substrate W. The precursor according to the embodiment of the present invention may be any one of trimethylamine (TMA), acetylacetone (AcAc), and hexafluoroacetylacetone (hfac). However, this embodiment is not limited thereto. The surface adsorption step (S160) may be performed at a second temperature, and the second temperature may be room temperature.

The second purging step (S180) is a step of supplying, by the gas supply unit 500, a purge gas to remove the precursor remaining in the processing space in the first chamber 200a. After the supply of the precursor is interrupted, the purge gas may be directly supplied to the processing space in the first chamber 200a without using plasma. Due to the supply of the purge gas, the precursor remaining in the processing space in the first chamber 200a after being supplied in the surface adsorption step (S160) and reaction by-products may be removed from the processing space. An inert gas, such as argon (Ar), helium (He), or nitrogen (N₂), may be used as the purge gas.

The etching step (S220) is a step of supplying heat to the processing space in the second chamber 200b in which the substrate W having undergone the modifying process (S100) is disposed to etch the thin film in units of atomic layers. The gas supply unit 500 may not supply gas to the processing space in the second chamber 200b, and heat may be supplied to the substrate W using a heating unit 600, thereby etching the thin film in units of atomic layers. In the etching step (S220), the surface layer of the modified film to which the precursor is adsorbed in the surface adsorption step (S160) is etched. The etching step (S220) according to the embodiment of the present invention may be performed at a third temperature, and the third temperature may be 250° C. to 400° C. An infrared lamp 610 may be used to supply heat to the substrate W. The thin film formed on the substrate W may be etched by supplying, using the heating unit 600, heat to the substrate W having binding energy weakened by the precursor physically adsorbed to the surface layer of the modified film in the surface adsorption step (S160).

The third purging step (S240) is a step of supplying, by the gas supply unit 500, a purge gas to remove etching by-products remaining in the processing space in the second chamber 200b. After the supply of heat is interrupted, the purge gas may be directly supplied to the processing space in the second chamber 200b without using plasma. Due to the supply of the purge gas, etching by-products remaining in the processing space after being generated in the etching step (S220) may be removed. An inert gas, such as argon (Ar), helium (He), or nitrogen (N₂), may be used as the purge gas.

Thereafter, a first determination step (S300) may be performed to determine whether a preset number of times condition is satisfied. In detail, the number of times processing is to be executed in accordance with the substrate processing method may be preset and stored as a control program in a storage device of a controller 700. In an example, based on the thickness of the modified film formed in the modifying step (S120) and the thickness by which the thin film is etched during one cycle including the surface adsorption step to the third purging step (S160 to S240), the number of iterations of performing the surface adsorption step to the third purging step (S160 to S240) in order to completely etch the modified film formed in the modifying step (S120) may be set in the controller 700.

For example, if the thickness of the modified film formed in the modifying step (S120) is about 11 Å and the thickness by which the thin film is etched by performing one cycle including the surface adsorption step to the third purging step (S160 to S240) is about 1 Å, the number of iterations of performing the surface adsorption step to the third purging step (S160 to S240) may be set to eleven in the controller 700, and the controller 700 may perform the processing based on the set number of iterations. If the set number of iterations has not been reached, this means that the modified film formed in the modifying step (S120) has not been completely etched. Thus, the processing may return to the surface adsorption step (S160), and the surface adsorption step to the third purging step (S160 to S240) may be repeated. If the set number of iterations has been reached, this means that the modified film formed in the modifying step (S120) has been completely etched. Thus, the processing may proceed to the next step, which is a second determination step (S400).

The second determination step (S400) is a step of determining whether the thin film is etched by a preset target etching thickness. If the thin film has not been etched by the preset target etching thickness, the processing may return to the modifying step (S120), and the modifying step to the third purging step (S120 to S240) may be performed. Here, the second determination step (S400) of determining whether the thin film is etched by the target etching thickness may be a step of determining whether the number of times of performing the modifying step reaches a preset number of modifications. For example, if the target etching thickness is 30 Å and the thickness of the modified film formed in the modifying step (S120) is 10 Å, a determination as to whether the number of modifications reaches three may be made. If the number of modifications has not reached three, the processing may return to the modifying step (S120), and if the number of modifications has reached three, the etching process may be terminated.

In this way, in the process of performing the processing in accordance with the above-described method, the number of times of performing the modifying step to the first purging step (S120 to S140) may be reduced, and thus the total processing time may be shortened.

As described above, the modifying process, in which a modifying gas converted into plasma is supplied to form a modified film having a predetermined thickness and a precursor is supplied and adsorbed to the surface of the substrate, may be performed in the first chamber, and the etching process, in which heat is supplied to etch the modified substrate, may be performed in the second chamber. Thereafter, through the determination steps, the modified film formed on the substrate and the modified film etched to a certain extent by performing one cycle of the etching process may be compared with each other. According to the present invention, if it is determined in the first determination step that the modified film formed on the substrate in the modifying step has not been completely etched, the processing may return to the surface adsorption step, and the surface adsorption step and the subsequent steps may be performed. If it is determined in the second determination step that the modified film formed on the substrate in the modifying step has been completely etched, the processing may return to the modifying step, and the modifying process and the etching process may be performed. Accordingly, the total processing time may be shortened, and thus productivity may be improved. Further, because the modifying process and the etching process are performed at different temperatures, deformation of the substrate due to temperature may be minimized.

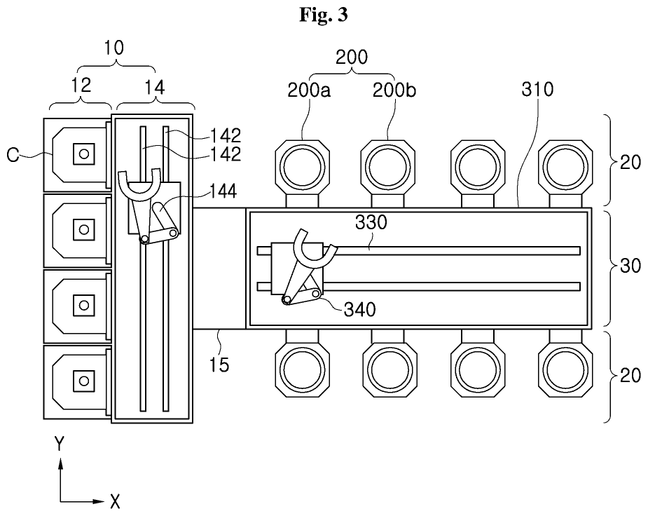

FIG. 3 is a plan view of a semiconductor manufacturing facility according to an embodiment of the present invention.

Referring to FIG. 3, the semiconductor manufacturing facility 1 may include an index block 10, a processing block 20, and a substrate transferring block 30 configured to transfer a substrate between the index block 10 and the processing block 20. According to the embodiment of the present invention, the index block 10 and the processing block 20 may be sequentially disposed in a line.

The index block 10 may include a load port 12, on which a carrier C storing a substrate is seated, and an index frame 14, which takes the substrate out of the carrier C seated on the load port 12 or transfers a substrate having undergone processing into the carrier C. The load port 12 is located opposite the processing block 20 with respect to the index frame 14. A plurality of carriers C storing substrates may be placed on the load port 12.

The index frame 14 may be provided therein with an index robot 144. The index robot 144 may be formed so as to be movable along a rail 142. The index robot 144 may serve to receive a substrate from the carrier C and transfer the substrate to a load lock chamber 15 configured to temporarily store substrates or to receive a substrate temporarily stored in the load lock chamber 15 and transfer the substrate into the carrier C.

The processing block 20 may be a device in which processing is performed on the substrate. The processing block 20 may include one or more processing chambers 200. A plurality of processing chambers 200 may be disposed. The respective processing chambers 200 may perform the same process or may perform different processes. Referring to FIGS. 4 and 5, according to the embodiment of the present invention, the first chamber 200a may perform the modifying process for modifying the substrate, and the second chamber 200b may perform the etching process for etching the modified substrate. These processing chambers 200a and 200b will be described in more detail later. Although the first chamber 200a and the second chamber 200b according to the embodiment of the present invention are illustrated as being disposed adjacent to each other to perform the processes, this embodiment is not limited thereto. In an example, the first chamber 200a and the second chamber 200b may be disposed so as to oppose each other or may be collinearly disposed at a predetermined interval.

The substrate transferring block 30 may be disposed adjacent to the processing block 20, and may serve to receive a substrate from the load lock chamber 15 and transfer the substrate to the processing block 20 or to transfer a substrate having undergone processing from the processing block 20 to the load lock chamber 15. The substrate transferring block 30 may include a rail 330 disposed in the direction in which the processing chambers 200 are disposed and a substrate transferring robot 340 configured to transfer the substrate while moving along the rail 330. The substrate transferring robot 340 may transfer the substrate while moving in an inner space in a transferring chamber 310.

FIG. 4 is a schematic cross-sectional view of the first chamber according to an embodiment of the present invention.

Referring to FIG. 4, the first chamber 200a may include a substrate support unit 300, a plasma generation unit 400, a gas supply unit 500, and a controller 700.

The first chamber 200a may include a processing space defined therein to allow a plasma process to be performed therein. The first chamber 200a may include an exhaust port 202 formed in a lower side thereof. The exhaust port 202 may be connected to an exhaust line on which a pump P is mounted. The exhaust port 202 may discharge reaction by-products generated during the plasma process and gas remaining in the first chamber 200a to the outside of the first chamber 200a through the exhaust line. In this case, pressure in the inner space in the first chamber 200a may be reduced to a predetermined pressure.

The first chamber 200a may include an opening 204 formed in the sidewall thereof. The opening 204 may function as a passage through which a substrate W is introduced into or removed from the first chamber 200a. The opening 204 may be configured to be opened and closed by a door assembly.

The substrate support unit 300 may be disposed in a lower area in the first chamber 200a. The substrate support unit 300 may support the substrate W using electrostatic force. However, this embodiment is not limited thereto. The substrate W may be supported in various ways, such as mechanical clamping or vacuum support.

The substrate support unit 300 may include a support body 302 and an electrostatic chuck 304 disposed on the upper surface of the support body 302. The electrostatic chuck 304 may be configured to electrostatically attract and hold the substrate W, and may include a ceramic layer provided with an electrode.

According to an embodiment of the present invention, although not shown, the substrate support unit 300 may be provided therein with a heating member and a cooling member to maintain the substrate W at a process temperature. The heating member may be a heating coil, and the cooling member may be provided as a cooling line through which refrigerant flows.

A pedestal 306 may be provided under the support body 302 in order to support the support body 302 and the electrostatic chuck 304. The pedestal 306 may be formed in a cylindrical shape having a predetermined height, and may have a space defined therein.

The plasma generation unit 400 may generate plasma in the processing space in the first chamber 200a. Plasma may be generated in an area above the substrate support unit 300 in the first chamber 200a. According to the embodiment of the present invention, the plasma generation unit 400 may generate plasma in the processing space in the first chamber 200a using a capacitively coupled plasma (CCP) source.

However, this embodiment is not limited thereto. The plasma generation unit 400 may also generate plasma in the processing space in the first chamber 200a using another type of plasma source, such as an inductively coupled plasma (ICP) source or microwaves.

The plasma generation unit 400 may include a high-frequency power supply 402 and a matching device 404. The high-frequency power supply 402 may supply high-frequency power to any one of an upper electrode and a lower electrode in order to generate a potential difference between the upper electrode and the lower electrode. Here, the upper electrode may be a shower head 410, and the lower electrode may be the substrate support unit 300.

The shower head 410 may be provided in the first chamber 200a so as to vertically oppose the electrostatic chuck 304. The shower head 410 may include a plurality of gas spray holes formed therein to evenly spray gas to the inside of the first chamber 200a, and may be formed to have a larger diameter than the electrostatic chuck 304. The shower head 410 may be made of a material containing a silicon component or a material containing a metal component.

The gas supply unit 500 may supply gas necessary for the process to the inside of the first chamber 200a. The gas supply unit 500 may include a gas source, a gas supply line, and a gas spray nozzle. The gas supply line may connect the gas source to the gas spray nozzle. The gas supply line may supply gas stored in the gas source to the gas spray nozzle. A gas valve may be mounted on the gas supply line in order to open and close the passage of the gas supply line or to regulate the flow rate of fluid flowing through the passage.

The gas supply unit 500 according to the embodiment of the present invention may include a plurality of gas sources 502, 512, and 522 for supplying a modifying gas, a precursor, and an inert gas, a plurality of gas supply lines 504, 514, and 524, and a plurality of gas valves 506, 516, and 526.

The gas source 502 for supplying a modifying gas may supply any one of oxygen, fluorine, and chlorine to the processing space in the first chamber 200a through the gas supply line 504 in order to modify the substrate W and thus to form a modified film. The gas valve 506 for regulating the flow rate of the modifying gas supplied may be provided on the gas supply line 504.

The gas source 512 for supplying a precursor may supply any one of trimethylamine (TMA), acetylacetone (AcAc), and hexafluoroacetylacetone (hfac) onto the modified film formed by the modifying gas in the processing space in the first chamber 200a through the gas supply line 514. The gas valve 516 for regulating the flow rate of the precursor supplied may be provided on the gas supply line 514.

The gas source 522 for supplying a purge gas may supply a purge gas to the processing space in the first chamber 200a through the gas supply line 524 after the supply of the modifying gas and the precursor is interrupted. The gas valve 526 for regulating the flow rate of the purge gas supplied may be provided on the gas supply line 524. The purge gas may be an inert gas, such as argon (Ar), helium (He), or nitrogen (N₂).

The controller 700 may perform control such that the modifying gas is supplied to the processing space in the first chamber 200a configured as described above, and is converted into plasma by the plasma generation unit 400. In addition, the controller 700 may perform control such that the gas supply unit 500 supplies the precursor to the processing space and the plasma generation unit 400 does not operate.

In addition, the controller 700 may perform control such that the substrate W having undergone the modifying step and the surface adsorption step is transferred to the second chamber 200b in order to etch the substrate W in units of atomic layers. In detail, in the first chamber 200a, the modifying gas may be supplied to modify the substrate W and thus to form a modified film, and the precursor may be supplied to be adsorbed to the surface of the modified film. Subsequently, the substrate W having undergone the modifying step and the surface adsorption step may be transferred to the second chamber 200b by the substrate transferring robot 340 of the substrate transferring block 30, and then the modified substrate W may be etched in units of atomic layers. While the substrate W is transferred from the first chamber 200a to the second chamber 200b, the substrate transferring block 30 may be maintained in a vacuum state.

FIG. 5 is a view showing a second chamber according to an embodiment of the present invention. The second chamber may perform a process of etching the modified substrate in units of atomic layers using an inert gas and heat without using plasma.

Referring to FIG. 5, the second chamber 200b is different from the first chamber 200a shown in FIG. 4 in that a process of etching the substrate W is performed using a heating unit 600 without using plasma.

A heating unit 600 may be provided in an upper side of the second chamber 200b in order to supply heat to the substrate W having the precursor adsorbed to the surface of the modified film and thus to etch the substrate W in units of atomic layers. The heating unit 600 may include a plurality of heating lamps 610 configured to generate thermal energy, and may supply heat to the substrate W placed below the heating unit 600 so as to oppose the heating unit 600. The heating lamps 610 according to the embodiment of the present invention may be infrared lamps, and may supply heat of 250° C. to 400° C. to the substrate W.

A window 620 may be provided between the heating lamps 610 and the substrate support unit 300. The window 620 may serve to prevent deposition of etching by-products generated as the process progresses on the heating lamps 610. For example, the window 620 may be a dielectric window. The window 620 may transmit light wavelengths generated by the heating lamps 610 so that heat is supplied to the substrate W. According to the present invention, the surface of the substrate W adsorbed with the precursor may be etched in units of atomic layers using heat supplied from the heating unit 600.

The second chamber 200b of the present invention having the above configuration may be a rapid thermal processing (RTP) apparatus, and may be used when a rapid increase in temperature in a short amount of time is required. In addition, the heating unit 600 provided in the second chamber 200b is not limited to the infrared lamp, and may include other types of thermal processing means enabling rapid thermal processing. For example, the heating unit 600 may include a microwave generator or a laser generator.

The controller 700 may perform control such that the gas supply unit 500 does not supply an inert gas while the heating unit 600 supplies heat to the substrate W disposed in the processing space in the second chamber 200b.

In addition, the controller 700 may comprehensively control the operation of the first chamber 200a and the second chamber 200b configured as described above. The controller 700 may be, for example, a computer, and may include a central processing unit (CPU), random access memory (RAM), read only memory (ROM), and an auxiliary storage device. The CPU may operate on the basis of a program stored in the ROM or the auxiliary storage device or a process condition to control the overall operation of the apparatus. In addition, a computer-readable program necessary for control may be stored in a storage medium. The storage medium may include, for example, a flexible disk, a compact disc (CD), a CD-ROM, a hard disk, a flash memory, a DVD, or the like.

The controller 700 according to the embodiment of the present invention may compare the thickness of the modified film formed in the modifying step with the thickness by which the thin film is etched during the surface adsorption step to the third purging step, and may preset the number of iterations of performing the surface adsorption step to the third purging step based thereon. If the set number of iterations has been reached, the controller 700 may transfer the substrate W having undergone the etching process to the first chamber 200a, and may re-perform the modifying step. If the set number of iterations has not been reached, the controller 700 may transfer the substrate W to the first chamber 200a, and may re-perform the surface adsorption step.

Although the first chamber 200a and the second chamber 200b according to the embodiment of the present invention have been described as performing the modifying process and the etching process, respectively, this embodiment is not limited thereto. In an example, in the case in which both the plasma generation unit 400 and the heating unit 600 are provided in one chamber, the corresponding chamber may perform both the modifying process and the etching process.

As is apparent from the above description, according to the present invention, a thin film formed on a substrate may be modified to form a modified film having a predetermined thickness, and a surface adsorption step and an etching step may be repeated multiple times, whereby the total processing time may be shortened, and productivity may be improved.

The effects achievable through the present invention are not limited to the above-mentioned effects, and other effects not mentioned herein will be clearly understood by those skilled in the art from the above description.

It will be apparent to those skilled in the art that various changes in form and details may be made without departing from the essential characteristics of the invention set forth herein. Accordingly, the above detailed description is not intended to be construed to limit the invention in all aspects and to be considered by way of example. The scope of the invention should be determined by reasonable interpretation of the appended claims and all equivalent modifications made without departing from the invention should be included in the following claims.

1. A substrate processing method of etching a thin film formed on a substrate in units of atomic layers, the substrate processing method comprising:
a modifying step of supplying a modifying gas to a processing space in a chamber accommodating the substrate to modify a surface of the thin film and form a modified film having a first thickness;
a surface adsorption step of supplying a precursor to the processing space to adsorb the precursor to the modified surface of the thin film; and
an etching step of supplying heat to the substrate adsorbed with the precursor to etch the modified surface of the thin film adsorbed with the precursor,
wherein the surface adsorption step and the etching step are repeatedly performed multiple times until the modified film having the first thickness is etched.

2. The substrate processing method according to claim 1, further comprising a first determination step of determining whether the surface adsorption step and the etching step are repeatedly performed a predetermined number of times.

3. The substrate processing method according to claim 2, wherein, upon determining in the first determination step that the surface adsorption step and the etching step have not been repeatedly performed the predetermined number of times, the method comprises re-performing the surface adsorption step and the etching step.

4. The substrate processing method according to claim 2, wherein, upon determining in the first determination step that the surface adsorption step and the etching step have been repeatedly performed the predetermined number of times, the method comprises a second determination step of determining whether a total etching thickness reaches a target etching thickness, and
wherein, upon determining in the second determination step that the total etching thickness has not reached the target etching thickness, the method comprises re-performing the modifying step.

5. The substrate processing method according to claim 1, wherein the modifying step is controlled such that a modified film forming process is performed in a diffusion limited region.

6. The substrate processing method according to claim 1, wherein, in the modifying step, the modifying gas supplied to the substrate comprises at least one of oxygen, fluorine, or chlorine.

7. The substrate processing method according to claim 1, wherein the modifying step is performed in a state of generating plasma in the processing space.

8. The substrate processing method according to claim 1, wherein any one of trimethylamine (TMA), acetylacetone (AcAc), and hexafluoroacetylacetone (hfac) is supplied to the substrate as the precursor to be adsorbed to a surface of the modified film.

9. The substrate processing method according to claim 1, wherein the modifying step is controlled at a first temperature,
wherein the surface adsorption step is controlled at a second temperature identical to the first temperature, and
wherein the etching step is controlled at a third temperature higher than the first temperature and the second temperature.

10. A substrate processing apparatus comprising:
a first chamber configured to modify a thin film formed on a substrate;
a second chamber configured to etch the substrate modified in the first chamber in units of atomic layers;
a substrate transferring robot configured to transfer the substrate between the first chamber and the second chamber; and
a controller,
wherein the first chamber comprises:
a plasma generation unit configured to generate plasma in a processing space in the first chamber; and
a gas supply unit configured to selectively supply a modifying gas and a precursor to the processing space in the first chamber,
wherein the second chamber comprises a heating unit configured to supply heat to a processing space in the second chamber, and
wherein the controller is configured to:
control the plasma generation unit and the gas supply unit to perform a modifying step of supplying the modifying gas to the processing space in the first chamber to modify a surface of the thin film of the substrate disposed in the processing space in the first chamber and form a modified film having a first thickness,
control the gas supply unit to perform a surface adsorption step of supplying the precursor to the processing space in the first chamber to adsorb the precursor to the modified surface of the thin film,
control the substrate transferring robot to transfer the substrate having undergone the surface adsorption step to the second chamber,
control the heating unit to perform an etching step of supplying heat to the substrate transferred to the second chamber to etch the modified surface of the thin film adsorbed with the precursor, and
perform control such that the surface adsorption step and the etching step are repeatedly performed multiple times until the modified film having the first thickness is etched.

11. The substrate processing apparatus according to claim 10, wherein the modifying gas comprises at least one of oxygen, fluorine, or chlorine.

12. The substrate processing apparatus according to claim 10, wherein the precursor is any one of trimethylamine (TMA), acetylacetone (AcAc), and hexafluoroacetylacetone (hfac).

13. The substrate processing apparatus according to claim 10, wherein the controller controls the plasma generation unit and the gas supply unit so that plasma of the modifying gas is generated in the processing space in the first chamber to modify a surface of the thin film formed on the substrate and the precursor is supplied to be adsorbed to the modified surface of the thin film.

14. The substrate processing apparatus according to claim 10, wherein the heating unit is any one of an infrared lamp, a laser generator, and a microwave generator.

15. The substrate processing apparatus according to claim 10, wherein the controller performs control such that a modified film forming process of the modifying step is performed in a diffusion limited region.

16. The substrate processing apparatus according to claim 10, wherein the controller controls the gas supply unit not to supply gas to the second chamber while the heating unit of the second chamber is driven.

17. A substrate processing method of etching a thin film formed on a substrate using a substrate processing apparatus comprising a first chamber and a second chamber, the substrate processing method comprising:
a modifying process of modifying the thin film formed on the substrate in the first chamber, the modifying process comprising a modifying step of supplying a modifying gas to a processing space in the first chamber accommodating the substrate to modify the thin film and to form a modified film having a first thickness, a first purging step of supplying a purge gas to the processing space in the first chamber to remove the modifying gas remaining in the processing space, a surface adsorption step of supplying a precursor to the processing space in the first chamber to adsorb the precursor to a surface of the modified film, and a second purging step of supplying a purge gas to the processing space in the first chamber to remove the precursor remaining in the processing space;
an etching process of etching the thin film modified in the first chamber in units of atomic layers in the second chamber, the etching process comprising an etching step of supplying heat to a processing space in the second chamber to etch the substrate adsorbed with the precursor and a third purging step of supplying a purge gas to the processing space in the second chamber to remove etching by-products remaining in the processing space; and
a first determination step of determining whether the surface adsorption step and the etching step are repeatedly performed a predetermined number of times,
wherein, upon determining in the first determination step that the surface adsorption step and the etching step have not been repeatedly performed the predetermined number of times, the method comprises re-performing the surface adsorption step and the etching step.

18. The substrate processing method according to claim 17, wherein, upon determining in the first determination step that the surface adsorption step and the etching step have been repeatedly performed the predetermined number of times, the method comprises a second determination step of determining whether a total etching thickness reaches a target etching thickness, and
wherein, upon determining in the second determination step that the total etching thickness has not reached the target etching thickness, the method comprises re-performing the modifying step.

19. The substrate processing method according to claim 18, wherein the modifying step is controlled such that a modified film forming process is performed in a diffusion limited region.

20. The substrate processing method according to claim 17, wherein the modifying gas comprises any one of oxygen, fluorine, and chlorine, and
wherein the precursor is any one of trimethylamine (TMA), acetylacetone (AcAc), and hexafluoroacetylacetone (hfac).
